(19) United States
(12) Patent Application Publication
(10) Pub. No.: US 2025/0192107 A1
(43) Pub. Date: Jun. 12, 2025

(54) SYSTEMS AND METHODS FOR HIGH BANDWIDTH MEMORY CONFIGURATIONS

(71) Applicant: Samsung Electronics Co., Ltd., Suwon-si (KR)

(72) Inventors: Hyoun Kwon JEONG, Pleasanton, CA (US); Soogil JEONG, Pleasanton, CA (US)

(21) Appl. No.: 18/679,410

(22) Filed: May 30, 2024

Related U.S. Application Data
(60) Provisional application No. 63/608,822, filed on Dec. 11, 2023.

(51) Int. Cl. H01L 25/065; H01L 23/498; H10B 80/00

(52) U.S. Cl. CPC H01L 25/0657; H01L 23/49827; H10B 80/00; H01L 2225/06541

(57) ABSTRACT

Provided are systems, methods, and apparatuses for high bandwidth memory configurations. In one or more examples, the systems, devices, and methods include positioning a first memory physical layer (PHY) interface on a surface of a compute die and connecting a first memory to the first memory PHY interface of the compute die via a first through-silicon via (TSV) connection. The systems, devices, and methods include connecting a second memory to a base die that connects to the compute die via a silicon interposer, positioning the compute die on the silicon interposer, and positioning the base die on the silicon interposer.

### CROSS-REFERENCE TO RELATED APPLICATIONS

This application claims the benefit of U.S. Provisional Patent Application Ser. No. 63/608,822, filed Dec. 11, 2023, which is incorporated by reference herein for all purposes.

### TECHNICAL FIELD

The disclosure relates generally to memory systems, and more particularly to high bandwidth memory configurations.

### BACKGROUND

The present background section is intended to provide context only, and the disclosure of any concept in this section does not constitute an admission that said concept is prior art.

With advances in technology, the size of electronic devices is decreasing while the amount of data is increasing rapidly as data is collected by devices such as mobile devices, Internet of things devices, aerial (remote sensing) devices, software logs, cameras, microphones, radio-frequency identification (RFID) readers, wireless sensor networks, and the like. As the size of electronics decreases, the amount of heat generated by components of such electronic devices (e.g., memory, processors, etc.) can increase. A need remains for systems and methods that improve efficient power usage in electronic devices.

The above information disclosed in this Background section is only for enhancement of understanding of the background of the disclosure and therefore it may contain information that does not constitute prior art.

### SUMMARY

In various embodiments, the systems and methods described herein include systems, methods, and apparatuses for high bandwidth memory configurations. In some aspects, the techniques described herein relate to a method of configuring memory, the method including: positioning a first memory physical layer (PHY) interface on a surface of a compute die; connecting a first memory to the first memory PHY interface of the compute die via a first through-silicon via (TSV) connection; connecting a second memory to a base die that connects to the compute die via a silicon interposer; positioning the compute die and the base die on the silicon interposer.

In some aspects, the techniques described herein relate to a method, wherein the first memory includes a first memory die stacked on the first memory PHY interface and a second memory die stacked on the first memory die.

In some aspects, the techniques described herein relate to a method, wherein: the first memory die connects to the first memory PHY interface via the first TSV connection, and the second memory die connects to the first memory die via the first TSV connection.

In some aspects, the techniques described herein relate to a method, wherein the second memory includes a third memory die stacked on the base die and a fourth memory die stacked on the third memory die.

In some aspects, the techniques described herein relate to a method, wherein: the third memory die connects to the base die via a second TSV connection, and the fourth memory die connect to the third memory die via the second TSV connection.

In some aspects, the techniques described herein relate to a method, wherein: the compute die includes a second memory PHY interface of the compute die, the first memory PHY interface is positioned on an inner surface of the compute die, and the second memory PHY interface is positioned on a side of the compute die.

In some aspects, the techniques described herein relate to a method, wherein the compute die includes a first die to die (D2D) interface positioned on a side of the compute die.

In some aspects, the techniques described herein relate to a method, wherein the compute die connects to a second compute die via a second D2D interface of the compute die and the silicon interposer.

In some aspects, the techniques described herein relate to a method, wherein the base die includes a memory PHY interface of the base die or a D2D interface of the base die.

In some aspects, the techniques described herein relate to a method, wherein the second memory or the first memory includes at least one of high-bandwidth memory, static random-access memory, dynamic random-access memory, or flash memory.

In some aspects, the techniques described herein relate to a method, wherein the compute die includes a graphical processing unit die.

In some aspects, the techniques described herein relate to a memory package including: a first memory physical layer (PHY) interface positioned on a surface of a compute die; a first memory connected to the first memory PHY interface of the compute die via a first through-silicon via (TSV) connection; a base die coupled with the compute die and positioned on a silicon interposer, wherein the compute die is positioned on the silicon interposer and connected to the base die via the silicon interposer; and a second memory connected to the base die.

In some aspects, the techniques described herein relate to a memory package, wherein the first memory includes a first memory die stacked on the first memory PHY interface and a second memory die stacked on the first memory die.

In some aspects, the techniques described herein relate to a memory package, wherein: the first memory die connects to the first memory PHY interface via the first TSV connection, and the second memory die connects to the first memory die via the first TSV connection.

In some aspects, the techniques described herein relate to a memory package, wherein the second memory includes a third memory die stacked on the base die and a fourth memory die stacked on the third memory die.

In some aspects, the techniques described herein relate to a memory package, wherein: the third memory die connects to the base die via a second TSV connection, and the fourth memory die connect to the third memory die via the second TSV connection.

In some aspects, the techniques described herein relate to a memory package, wherein: the compute die includes a second memory PHY interface of the compute die, the first memory PHY interface is positioned on an inner surface of the compute die, and the second memory PHY interface is positioned on a side of the compute die.

In some aspects, the techniques described herein relate to a system on chip (SoC) including: a compute die positioned on a silicon interposer; a base die coupled with the compute die and positioned on the silicon interposer; and a memory coupled with the compute die and the base die, the memory including: a first memory physical layer (PHY) interface positioned on a surface of the compute die; a first memory connected to the first memory PHY interface of the compute die via a first through-silicon via (TSV) connection; and a second memory connected to the base die via a second TSV connection.

In some aspects, the techniques described herein relate to a SoC, wherein the first memory includes a first memory die stacked on the first memory PHY interface and a second memory die stacked on the first memory die.

In some aspects, the techniques described herein relate to a SoC, wherein: the first memory die connects to the first memory PHY interface via the first TSV connection, and the second memory die connects to the first memory die via the first TSV connection.

A computer-readable medium is disclosed. The computer-readable medium can store instructions that, when executed by a computer, cause the computer to perform substantially the same or similar operations as described herein are further disclosed. Similarly, non-transitory computer-readable media, devices, and systems for performing substantially the same or similar operations as described herein are further disclosed.

### BRIEF DESCRIPTION OF THE DRAWINGS

The above-mentioned aspects and other aspects of the present systems and methods will be better understood when the present application is read in view of the following figures in which like numbers indicate similar or identical elements. Further, the drawings provided herein are for purpose of illustrating certain embodiments only; other embodiments, which may not be explicitly illustrated, are not excluded from the scope of this disclosure.

These and other features and advantages of the present disclosure will be appreciated and understood with reference to the specification, claims, and appended drawings wherein:

FIG. 1 illustrates an example system in accordance with one or more implementations as described herein.

FIG. 2 illustrates details of the system of FIG. 1, according to one or more implementations as described herein.

FIG. 3 illustrates an example system in accordance with one or more implementations as described herein.

FIG. 4 illustrates an example system in accordance with one or more implementations as described herein.

FIG. 5 illustrates an example system in accordance with one or more implementations as described herein.

FIG. 6 illustrates an example system in accordance with one or more implementations as described herein.

FIG. 7 illustrates an example system in accordance with one or more implementations as described herein.

FIG. 8 illustrates an example system in accordance with one or more implementations as described herein.

FIG. 9 depicts a flow diagram illustrating an example method associated with the disclosed systems, in accordance with example implementations described herein.

FIG. 10 depicts a flow diagram illustrating an example method associated with the disclosed systems, in accordance with example implementations described herein.

While the present systems and methods are susceptible to various modifications and alternative forms, specific embodiments thereof are shown by way of example in the drawings and will herein be described. The drawings may not be to scale. It should be understood, however, that the drawings and detailed description thereto are not intended to limit the present systems and methods to the particular form disclosed, but to the contrary, the intention is to cover all modifications, equivalents, and alternatives falling within the spirit and scope of the present systems and methods as defined by the appended claims.

### DETAILED DESCRIPTION OF VARIOUS EMBODIMENTS

The details of one or more embodiments of the subject matter described herein are set forth in the accompanying drawings and the description below. Other features, aspects, and advantages of the subject matter will become apparent from the description, the drawings, and the claims.

Various embodiments of the present disclosure now will be described more fully hereinafter with reference to the accompanying drawings, in which some, but not all embodiments are shown. Indeed, the disclosure may be embodied in many forms and should not be construed as limited to the embodiments set forth herein; rather, these embodiments are provided so that this disclosure will satisfy applicable legal requirements. The term “or” is used herein in both the alternative and conjunctive sense, unless otherwise indicated. The terms “illustrative” and “example” are used to be examples with no indication of quality level. Like numbers refer to like elements throughout. Arrows in each of the figures depict bi-directional data flow and/or bi-directional data flow capabilities. The terms “path,” “pathway” and “route” are used interchangeably herein.

Embodiments of the present disclosure may be implemented in various ways, including as computer program products that comprise articles of manufacture. A computer program product may include a non-transitory computer-readable storage medium storing applications, programs, program components, scripts, source code, program code, object code, byte code, compiled code, interpreted code, machine code, executable instructions, and/or the like (also referred to herein as executable instructions, instructions for execution, computer program products, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (for example a solid-state drive (SSD)), solid state card (SSC), solid state module (SSM), enterprise flash drive, magnetic tape, or any other non-transitory magnetic medium, and/or the like. A non-volatile computer-readable storage medium may include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may include read-only memory (ROM), programmable read-only memory (PROM), erasable programmable read-only memory (EPROM), electrically erasable programmable read-only memory (EEPROM), flash memory (for example Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), graphic DDR (GDDR), Rambus dynamic random access memory (RDRAM), Twin Transistor RAM (TTRAM), Thyristor RAM (T-RAM), Zero-capacitor (Z-RAM), Rambus in-line memory component (RIMM), dual in-line memory component (DIMM), single in-line memory component (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As should be appreciated, various embodiments of the present disclosure may be implemented as methods, apparatus, systems, computing devices, computing entities, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may take the form of an entirely hardware embodiment, an entirely computer program product embodiment, and/or an embodiment that comprises a combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (for example the executable instructions, instructions for execution, program code, and/or the like) on a computer-readable storage medium for execution. For example, retrieval, loading, and execution of code may be performed sequentially, such that one instruction is retrieved, loaded, and executed at a time. In some example embodiments, retrieval, loading, and/or execution may be performed in parallel, such that multiple instructions are retrieved, loaded, and/or executed together. Thus, such embodiments can produce specifically configured machines performing the steps or operations specified in the block diagrams and flowchart illustrations. Accordingly, the block diagrams and flowchart illustrations support various combinations of embodiments for performing the specified instructions, operations, or steps.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not be necessarily all referring to the same embodiment. Furthermore, the particular features, structures or characteristics may be combined in any suitable manner in one or more embodiments. In this regard, as used herein, the word “exemplary” means “serving as an example, instance, or illustration. Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. Similarly, various waveforms and timing diagrams are shown for illustrative purpose only. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and case of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-chip (SoC), an assembly, and so forth.

Increasing the number of memory channels can be a design consideration for increasing data processing, decreasing latency, and reducing power usage of computing system (e.g., artificial intelligence (AI) system on chip (SoC)). Stacking memory directly on one or more compute dies can increase the number of memory channels. In some cases, the memory may be stacked based on through-silicon via (TSV) bonding. TSV can include a packaging technology that uses vertical electrical connections between silicon wafers or dies to replace the conventional wires used to connect chips. TSVs can be used to create 2.5D and/or 3D packages that contain multiple semiconductor dies.

The systems and methods described herein combine 3D-stacking and 2.5D packaging to maximize the number of memory channels of a given system. The systems and methods implement the edge of die and the top of die (e.g., front surface) to increase compute die memory bandwidth. 2.5D stacking can include a technique (e.g., of interposer technology) that arranges two or more semiconductor chips (e.g., side-by-side) on a silicon interposer. The devices are typically manufactured separately and delivered to the assembly house as bare dies. The base, or interposer, can provide connectivity between the devices. 2.5D packaging can be used for applications with low power and/or high-performance constraints. The front surface of a semiconductor chip can include the surface of a silicon wafer where circuits are formed. The wafer may be a thin slice of a cylindrical silicon ingot, with a diameter ranging from 50 mm to 300 mm. On the wafer's surface, hundreds of semiconductors with the same circuit may be formed in a lattice-like arrangement.

Three-dimensional (3D), or 3D integrated circuit (3D IC) technology, may be based on a process of packaging two or more chips vertically (e.g., in the same package). The devices can be interconnected using through-silicon vias (TSVs), copper-copper (Cu—Cu) connections, TSV bond pad metal (TSV-BPM) bonding, hybrid bonding, wafer-on-wafer bonding, and/or integrated-SoC (SoIC) bonding. A first chip in a 3D stacked package can have a different function than a second chip in the package. 3D stacking can improve performance, power, and cost, while also addressing challenges around power delivery and thermal management. A 3D IC can be configured to function as a single device to achieve performance improvements at reduced power and smaller footprint than conventional two-dimensional packages.

In some cases, the systems and methods may implement an interposer to implement the combination of 3D-stacking and 2.5D packaging. An interposer (e.g., silicon interposer) can be an electrical interface routing between one socket or connection to another. The purpose of an interposer may be to spread a connection to a wider pitch or to reroute a connection to a different connection. A silicon interposer can be a passive silicon component that is placed on a package substrate and that holds active dies. An interposer can allow for signal remapping from one active chip to another. Interposers can be used in multi die chips or boards. The interposer can act as a bridge, connecting individual dies and providing a high-speed communication interface. Interposers can provide high connectivity between a die and connected components. Interposers may be used in ball-grid array (BGA) packages, multi-chip modules, and/or high bandwidth memory.

In some cases, the systems and methods may implement microbump technology to implement the combination of 3D-stacking and 2.5D packaging. In some configurations, a chip may be connected to an interposer using microbump technology. Microbump technology may be referred to as micro-bump bonding (MBB), and can allow for the 3D integration of semiconductor devices. MBB can include an integrated circuit (IC) chip with bumps, a circuit substrate, and a bonding adhesive. The binding force of the adhesive can create electrical connections between the bumps on the IC. In some cases, a silicon substrate, serving as an interposer, may be connected to a substrate through bump connections. The surface of the silicon substrate may be interconnected using redistribution layer (RDL) wiring, while TSVs may act as conduits for electrical connections between upper and lower surfaces of the silicon substrate.

In some cases, the systems and methods may implement a base die to implement the combination of 3D-stacking and 2.5D packaging. The base die can refer to a bottom-most layer in stacked memory. In some examples, a buffer die may be used in addition to or as an alternative to a base die. In some cases, the base die may include and/or be referred to as a buffer die. In some cases, the base die may be configured to control a stacked memory (e.g., high-bandwidth memory (HBM)). Adding a base die to a stack of memory dies can improve signal quality and signal strength, increasing memory bandwidth.

In some cases, the systems and methods may implement memory physical layer (PHY) interfaces to implement the combination of 3D-stacking and 2.5D packaging. HBM may be coupled to a physical layer IP interface (PHY). In some cases, an HBM PHY can receive data, parity, and HBM DRAM row-column commands from memory controllers through DDR PHY interfaces (DFIs), and then pass them to HBM memory using the HBM DRAM interface. DFI can include an interface protocol that defines signals, timing, and programmable parameters used to transfer control information and data to and from the DRAM devices, and/or between a microcontroller and PHY (e.g., HBM PHY, HBM 3D PHY). It is noted that the terms high-bandwidth memory and HBM may be descriptions in the art understood to describe a form of memory. However, the terms high-bandwidth memory and HBM can mean any suitable memory that includes one or more characteristics, including at least one of relatively wide communication lanes (e.g., 4096-bit interface that connects to CPU or GPU), relatively low power consumption (e.g., lower power than GDDR), relatively high capacity (e.g., higher capacity than GDDR), relatively high bandwidth (e.g., bandwidth up to 1TB/s), resides on a silicon interposer (e.g., resides on the same silicon interposer as the processing unit), and/or 3D stacking.

In some cases, the systems and methods may implement a die-to-die (D2D) interface to implement the combination of 3D-stacking and 2.5D packaging. A D2D interface can include a functional block that allows for a data link between two silicon dies that are assembled in the same package. D2D interfaces can be used in applications such as networking, high-performance computing (HPC), hyperscale data center, and AI systems. D2D interfaces can provide high-speed, low-latency communication between two dies.

A compute die based on the systems and methods described may be fabricated with a first memory interface (e.g., HBM PHY) on the side or edge of the compute die as well as a second memory interface (e.g., 3D HBM PHY) on the front surface of the compute die. In some examples, multiple compute dies (e.g., four compute dies) may be connected to one another via respective D2D interfaces. Based on the multiple compute dies and the systems and methods described herein, 32 memory packages (e.g., 32 HBM packages) may be integrated within a single package. Based on the multiple compute dies, the systems and methods can provide relatively high levels of memory bandwidth (e.g., a single multi-die package can support 64 TB/s of HBM bandwidth based on HBM4 with 2 TB/s memory bandwidth per HBM package).

High performance applications such as AI, have increasing demand for speed and efficiency. According to some embodiments described herein, one or more hybrid arrangements and layouts of 2.5D and 3D stacked HBM provide faster and more efficient memory systems. In some embodiments, the number of HBM channels may be greatly increased to accommodate this growing demand.

The systems and methods described herein include multiple advantages and benefits. For example, the hybrid memory stacking systems and methods described maximize the number of memory channels (e.g., HBM channels) on a given system (e.g., AI compute SoC). The hybrid memory stacking systems and methods increase memory bandwidth and capacity by utilizing both edge inputs/outputs (I/Os) and front surface I/Os (e.g., based on TSV connections). The hybrid memory stacking systems and methods described herein reduce memory access latency and increase power efficiency based on combining 3D-stacking and 2.5D packaging.

According to some embodiments described herein, devices or methods may include a first circuit with a first three-dimensional (3D) stacked HBM. The devices may also include a second circuit, connected to the first circuit, with a 2.5D stacked HBM.

The first circuit may be connected to the second circuit via a silicon interposer in some embodiments. The second circuit may include an HBM base die (e.g., HBM buffer die), according to some embodiments. The HBM base die may communicate with a silicon interposer via a first HBM PHY connection on the HBM base die, in some embodiments. The HBM base die may further communicate with the first circuit via a second HBM PHY connection on the first circuit, in some embodiments. The first circuit may be connected to a third circuit including a second 3D stacked HBM, in some embodiments. The first circuit may be connected to the third circuit via a die to die (D2D) interface. The first circuit may also include four 3D stacked HBMs according to some embodiments. Implementations of the described techniques may include hardware, a method or process, or computer software on a computer-accessible medium.

In some embodiments, the apparatus may include a first compute die with a first 3D stacked HBM, and a host. The apparatus may also include a first circuit, connected to the first compute die with a 2.5D stacked HBM according to some embodiments.

According to some embodiments, the host may distribute data to the 3D stacked HBM and the 2.5D stacked HBM. The first compute die may be connected to the first circuit via an interposer, according to some embodiments. The first circuit further may include an HBM base die. The HBM base die may communicate via the interposer via a first HBM PHY connection on the HBM base die. The HBM base die may further communicate with the first compute die via a second HBM PHY connection on the first compute die. The first compute die may be connected to a second compute die including a second 3D stacked HBM. The first compute die may be connected to the second compute die via a die-to-die interface, in some embodiments. The first compute die and second compute die each may have eight 3D stacked HBMs, in some embodiments. The first compute die and second compute die each may have at least two circuits with 2.5D stacked HBM connected to the respective first and second compute die. The first compute die and second compute die each may have sixteen 3D stacked HBMs in some embodiments.

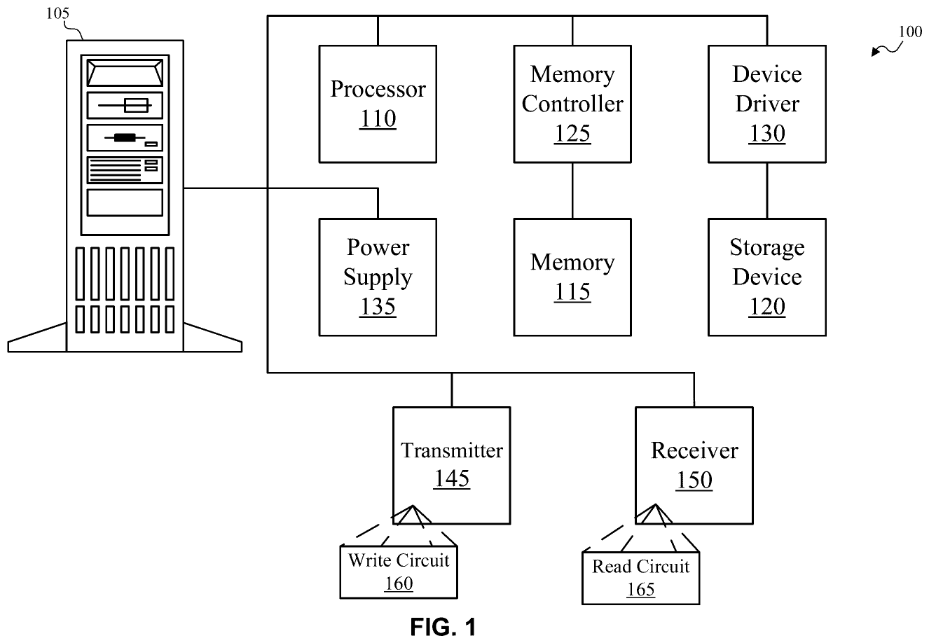

FIG. 1 illustrates an example system 100 in accordance with one or more implementations as described herein. In FIG. 1, machine 105, which may be termed a host, a system, or a server, is shown. While FIG. 1 depicts machine 105 as a tower computer, embodiments of the disclosure may extend to any form factor or type of machine. For example, machine 105 may be a rack server, a blade server, a desktop computer, a tower computer, a mini tower computer, a desktop server, a laptop computer, a notebook computer, a tablet computer, etc.

Machine 105 may include processor 110, memory 115, and storage device 120. Processor 110 may be any variety of processor. It is noted that processor 110, along with the other components discussed below, are shown outside the machine for ease of illustration: embodiments of the disclosure may include these components within the machine. While FIG. 1 shows a single processor 110, machine 105 may include any number of processors, each of which may be single core or multi-core processors, each of which may implement a Reduced Instruction Set Computer (RISC) architecture or a Complex Instruction Set Computer (CISC) architecture (among other possibilities), and may be mixed in any desired combination.

Processor 110 may be coupled to memory 115. Memory 115 may be any variety of memory, such as flash memory, Dynamic Random Access Memory (DRAM), Static Random Access Memory (SRAM), Persistent Random Access Memory, Ferroelectric Random Access Memory (FRAM), or Non-Volatile Random Access Memory (NVRAM), such as Magnetoresistive Random Access Memory (MRAM), Phase Change Memory (PCM), or Resistive Random-Access Memory (ReRAM). Memory 115 may include volatile and/or non-volatile memory. Memory 115 may use any desired form factor: for example, Single In-Line Memory Module (SIMM), Dual In-Line Memory Module (DIMM), Non-Volatile DIMM (NVDIMM), etc. Memory 115 may be any desired combination of different memory types, and may be managed by memory controller 125. Memory 115 may be used to store data that may be termed “short-term”: that is, data not expected to be stored for extended periods of time. Examples of short-term data may include temporary files, data being used locally by applications (which may have been copied from other storage locations), and the like. Memory 115 may include 3D stacked memory (e.g., 3D HBM) and/or 2.5D stacked memory (e.g., 2.5D HBM). In some cases, at least a portion of memory 115 may be stacked on processor 110. For example, at least a portion of memory 115 may be stacked on a front surface of a compute die of processor 110 (e.g., 3D HBM). Additionally, or alternatively, at least a portion of memory 115 may be stacked on a side or an edge of a compute die of processor 110 (e.g., 2.5D HBM).

Processor 110 and memory 115 may support an operating system under which various applications may be running. These applications may issue requests (which may be termed commands) to read data from or write data to either memory 115 or storage device 120. When storage device 120 is used to support applications reading or writing data via some sort of file system, storage device 120 may be accessed using device driver 130. While FIG. 1 shows one storage device 120, there may be any number (one or more) of storage devices in machine 105. Storage device 120 may support any desired protocol or protocols, including, for example, the Non-Volatile Memory Express (NVMe) protocol, a Serial Attached Small Computer System Interface (SCSI) (SAS) protocol, or a Serial AT Attachment (SATA) protocol. Storage device 120 may include any desired interface, including, for example, a Peripheral Component Interconnect Express (PCle) interface, or a Compute Express Link (CXL) interface. Storage device 120 may take any desired form factor, including, for example, a U.2 form factor, a U.3 form factor, a M.2 form factor, Enterprise and Data Center Standard Form Factor (EDSFF) (including all of its varieties, such as E1 short, E1 long, and the E3 varieties), or an Add-In Card (AIC).

While FIG. 1 uses the term “storage device,” embodiments of the disclosure may include any storage device formats that may benefit from the use of computational storage units, examples of which may include hard disk drives, Solid State Drives (SSDs), or persistent memory devices, such as PCM, ReRAM, or MRAM. Any reference to “storage device” “SSD” below should be understood to include such other embodiments of the disclosure and other varieties of storage devices. In some cases, the term “storage unit” may encompass storage device 120 and memory 115.

Machine 105 may include power supply 135. Power supply 135 may provide power to machine 105 and its components. Machine 105 may include transmitter 145 and receiver 150. Transmitter 145 or receiver 150 may be respectively used to transmit or receive data. In some cases, transmitter 145 and/or receiver 150 may be used to communicate with memory 115 and/or storage device 120. Transmitter 145 may include write circuit 160, which may be used to write data into storage, such as a register, in memory 115 and/or storage device 120. In a similar manner, receiver 150 may include read circuit 165, which may be used to read data from storage, such as a register, from memory 115 and/or storage device 120.

In one or more examples, machine 105 may be implemented with any type of apparatus. Machine 105 may be configured as (e.g., as a host of) one or more of a server such as a compute server, a storage server, storage node, a network server, a supercomputer, data center system, and/or the like, or any combination thereof. Additionally, or alternatively, machine 105 may be configured as (e.g., as a host of) one or more of a computer such as a workstation, a personal computer, a tablet, a smartphone, and/or the like, or any combination thereof. Machine 105 may be implemented with any type of apparatus that may be configured as a device including, for example, an accelerator device, a storage device, a network device, a memory expansion and/or buffer device, a central processing unit (CPU), a graphics processing unit (GPU), a neural processing unit (NPU), a tensor processing unit (TPU), and/or the like, or any combination thereof.

Any communication between devices including machine 105 (e.g., host, computational storage device, and/or any intermediary device) can occur over an interface that may be implemented with any type of wired and/or wireless communication medium, interface, protocol, and/or the like including PCIc, NVMe, Ethernet, NVM Express over Fabrics (NVMe-oF), Compute Express Link (CXL), and/or a coherent protocol such as CXL.mem, CXL.cache, CXL.IO and/or the like, Gen-Z, Open Coherent Accelerator Processor Interface (OpenCAPI), Cache Coherent Interconnect for Accelerators (CCIX), Advanced extensible Interface (AXI) and/or the like, or any combination thereof, Transmission Control Protocol/Internet Protocol (TCP/IP), FibreChannel, InfiniBand, Serial AT Attachment (SATA), Small Computer Systems Interface (SCSI), Serial Attached SCSI (SAS), iWARP, any generation of wireless network including 2G, 3G, 4G, 5G, and/or the like, any generation of Wi-Fi, Bluetooth, near-field communication (NFC), and/or the like, or any combination thereof. In some embodiments, the communication interfaces may include a communication fabric including one or more links, buses, switches, hubs, nodes, routers, translators, repeaters, and/or the like. In some embodiments, system 100 may include one or more additional apparatus having one or more additional communication interfaces.

The functionality of the systems and methods described herein, including any of the host functionality (e.g., machine 105), device functionally, component functionality, and/or the like, may be implemented with hardware, software, firmware, or any combination thereof including, for example, hardware and/or software combinational logic, sequential logic, timers, counters, registers, state machines, volatile memories such as dynamic random access memory (DRAM) and/or static random access memory (SRAM), nonvolatile memory including flash memory, persistent memory such as cross-gridded nonvolatile memory, memory with bulk resistance change, phase change memory (PCM), and/or the like and/or any combination thereof, complex programmable logic devices (CPLDs), field programmable gate arrays (FPGAs), application specific integrated circuits (ASICs) CPUs including complex instruction set computer (CISC) processors such as x86 processors and/or reduced instruction set computer (RISC) processors such as RISC-V and/or ARM processors), graphics processing units (GPUs), neural processing units (NPUs), tensor processing units (TPUs) and/or the like, executing instructions stored in any type of memory. In some embodiments, one or more components of the systems and methods may be implemented as a system-on-chip (SoC). In some cases, machine 105 may be an example of an SoC (e.g., AI compute SoC) based on the systems and methods described herein.

In some examples, the hybrid memory stacking systems and methods described herein enhance the operation of logic (e.g., logical circuit), hardware (e.g., processing unit, memory, storage), software, firmware, and the like. The hybrid memory stacking systems and methods may improve the operation of any one or combination of multiplexers, registers, logic gates, arithmetic logic units (ALUs), cache, computer memory, microprocessors, processing units (CPUs, GPUS, NPUs, and/or TPUs), FPGAs, ASICs, etc.

The systems and methods described herein include multiple advantages and benefits. For example, the hybrid memory stacking systems and methods described maximize the number of memory channels (e.g., HBM channels) on a given system (e.g., AI compute SoC). The hybrid memory stacking systems and methods increase memory bandwidth and capacity by utilizing both edge I/Os and front surface I/Os (e.g., based on TSV connections). The hybrid memory stacking systems and methods described herein reduce memory access latency and increase power efficiency based on combining 3D-stacking and 2.5D packaging.

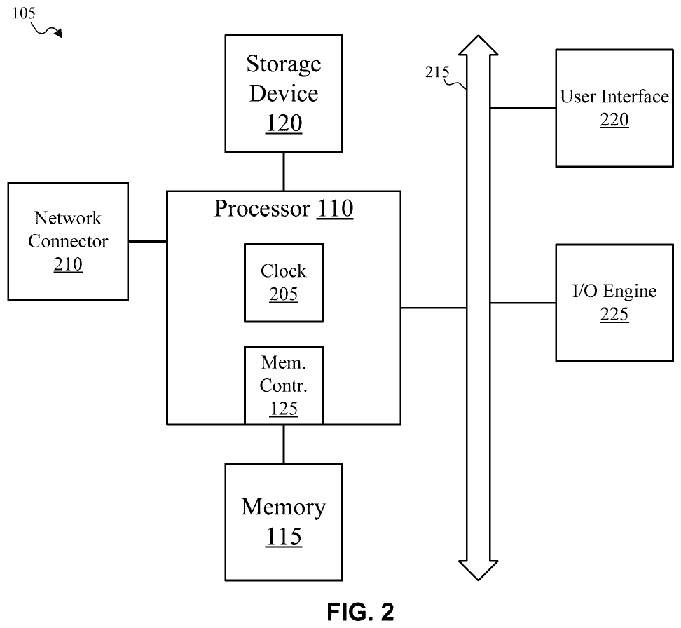

FIG. 2 illustrates details of machine 105 of FIG. 1, according to examples described herein. In the illustrated example, machine 105 may include one or more processors 110, which may include memory controllers 125 and clocks 205, which may be used to coordinate the operations of the components of the machine. Processors 110 may be coupled to memories 115, which may include random access memory (RAM), read-only memory (ROM), or other state preserving media, as examples. Processors 110 may be coupled to storage devices 120, and to network connector 210, which may be, for example, an Ethernet connector or a wireless connector. Processors 110 may be connected to buses 215, to which may be attached user interfaces 220 and Input/Output (I/O) interface ports that may be managed using I/O engines 225, among other components.

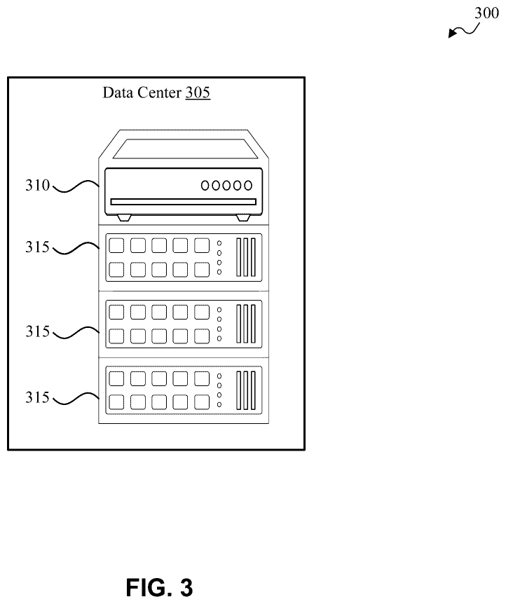

FIG. 3 illustrates an example system 300 in accordance with one or more implementations as described herein. In the illustrated example, system 300 includes data center 305. In some embodiments, one or more data center racks 315 may be used, including any number or configuration of 2.5D and 3D stacked memory. At least one data center rack 315 may have, for example, a top of rack router 310. The top of rack router 310 may include a routing device configured to receive signaling, route processing and/or data requests to at least one data center rack 315, and the like.

At least one data center rack 315 may include any number of combination of 2.5D stacked memory (e.g., 2.5D HBM) and/or 3D stacked memory (e.g., 3D HBM), where the 2.5D stacked memory and/or the 3D stacked memory may be stacked in relation to a compute die. In some cases, the 2.5D stacked memory may be positioned adjacent to the compute die and the 3D stacked memory may be stacked on a surface of the compute die. The compute die may include at least one of a graphics processing unit (GPU), a central processing unit (CPU), a tensor processing unit (TPU), a neural processing unit (NPU), a vision processing unit (VPU), a field programmable gate array (FPGA), a quantum processor, a microprocessor, physics processing unit, or host/controller device, etc. The arrangement of the 2.5D and 3D stacked memory may be in any manner, including a grid, a series, an organic arrangement, etc. The number of 2.5D and 3D HBM stacks in some embodiments may be a factor of two, for example, 8, 16, 32 or 64, or any combination allowed per die size and available space and technology.

Any of the functionality disclosed herein may be implemented with hardware, software, or a combination thereof including combinational logic, sequential logic, one or more timers, counters, registers, and/or state machines, one or more complex programmable logic devices (CPLDs), FPGAs, application specific integrated circuits (ASICs), CPUs such as complex instruction set computer (CISC) processors such as x86 processors and/or reduced instruction set computer (RISC) processors such as ARM processors, GPUs, NPUs, TPUs and/or the like, executing instructions stored in any type of memory, or any combination thereof. In some embodiments, one or more components may be implemented as an SoC (e.g., AI compute SoC).

In some embodiments, storage may be separately arranged on individual data center racks 315. Any variation on amount, location and configuration of storage may be considered. Any of the storage devices disclosed herein may communicate through any interfaces and/or protocols including PCle, NVMe, NVMe-oF, Ethernet, TCP/IP, User Datagram Protocol (UDP), remote direct memory access (RDMA), RDMA over Converged Ethernet (ROCE), FibreChannel, InfiniBand, SATA, SCSI, SAS, iWARP, Hypertext Transfer Protocol (HTTP), HBM PHY, HBM 3D PHY, D2D, and/or the like, or any combination thereof.

In some embodiments, one or more storage devices may be implemented with multiple storage devices arranged, for example, in one or more servers. They may be configured, for example, in one or more server chassis, server racks, groups of server racks, data rooms, datacenters, edge data centers, mobile edge datacenters, and/or the like, and/or any combination thereof. In some embodiments, data center 305 may be implemented with one or more storage server clusters.

In some examples, data center 305 may be implemented with any type and/or configuration of network resources. For example, data center 305 may include any type of network fabric such as Ethernet, Fibre Channel, InfiniBand, and/or the like, using any type of network protocols such as transmission control protocol/internet protocol (TCP/IP), RoCE, and/or the like. In some cases, data center 305 may include any type of storage interfaces and/or protocols such as SATA, SCSI, SAS, NVMe, NVMe-oF, and/or the like. In some embodiments, the data center 305 and/or at least one data center rack 315 may be implemented with one or more networks and/or network segments interconnected with one or more switches, routers, bridges, hubs, and/or the like.

The semiconductor devices described herein, may be encapsulated using various packaging techniques. For example, semiconductor devices constructed according to principles of the disclosed subject matter may be encapsulated using any one of a package on package (POP) technique, a ball grid arrays (BGAs) technique, Land Grid Array (LGA), a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline package (SOIC) technique, a shrink small outline package (SSOP) technique, a thin small outline package (TSOP) technique, a thin quad flat package (TQFP) technique, a system in package (SIP) technique, a multi-chip package (MCP) technique, a wafer-level fabricated package (WFP) technique, a wafer-level processed stack package (WSP) technique, or other technique as will be known to those skilled in the art.

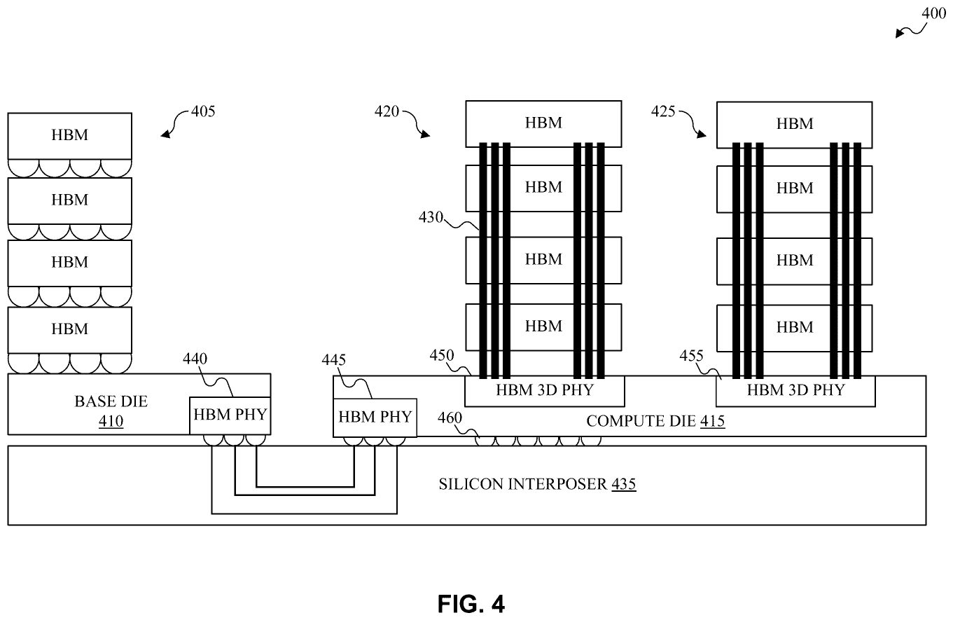

FIG. 4 illustrates an example system 400 in accordance with one or more implementations as described herein. System 400 may represent a side view of a system based on high bandwidth memory configurations. In the illustrated example, system 400 includes one or more 2.5D HBM stacks (e.g., HBM stack 405), base die 410 (e.g., buffer die), compute die 415, one or more 3D HBM stacks (e.g., HBM stack 420, HBM stack 425), TSV 430, silicon interposer 435, HBM PHY 440, HBM PHY 445, HBM 3D PHY 450, and HBM 3D PHY 455. As shown, HBM stack 405 includes a stack of HBM. Although system 400 is depicted with stacks of HBM, other memory types are contemplated, additionally, or alternatively, which may include at least one of RAM, DRAM, SRAM, FPM DRAM, EDO DRAM, SDRAM, DDR SDRAM, DDR2 SDRAM, DDR3 SDRAM, RDRAM, TTRAM, T-RAM, Z-RAM, RIMM, DIMM, SIMM, VRAM, cache memory (including various levels), flash memory, register memory, other types of memory, and/or any combination thereof.

System 400 may include various electrical connections, which may include electrical power connections, timing connections (e.g., clock signal), and/or electrical data communication connections (e.g., input/output connections). Although system 400 provides an example of a given electrical connection, any of the electrical connections of system 400 may include at least one of TSVs, TSV-BPM bonding, Cu-Cu connections, hybrid bonding, microbumps, wafer-on-wafer bonding, and/or integrated-SoC (SoIC) bonding. As shown, base die 410 (e.g., an HBM base die, HBM buffer die) may connect electrically to compute die 415, HBM stack 405 may connect electrically to base die 410, HBM stack 420 may connect electrically to HBM 3D PHY 450, and/or HBM stack 425 may connect electrically to an HBM 3D PHY 455.

In the illustrated example, HBM stack 405 includes a stack of memory where each layer of memory is electrically connected (e.g., a first layer memory die connected to a second layer memory die, the second layer memory die connected to a third layer memory die, etc.). In some cases, HBM stack 405 may include 2.5D stacked HBM. As shown, a first layer of HBM stack 405 may be electrically connected to base die 410. In some cases, the electrical connections of HBM stack 405 and/or base die 410 may include at least one of TSVs, TSV-BPM bonding, Cu-Cu connections, hybrid bonding, microbumps, wafer-on-wafer bonding, and/or integrated-SoC (SoIC) bonding. As shown, HBM PHY 440 may connect electrically to HBM PHY 445 through silicon interposer 435. Thus, base die 410 may connect electrically to compute die 415 through HBM PHY 440, silicon interposer 435, and HBM PHY 445. In some cases, HBM PHY 440 and/or HBM PHY 445 may include a D2D interface. For example, base die 410 may connect to compute die 415 via an HBM PHY connection and/or a D2D connection.

In the illustrated example, HBM stack 420 and HBM stack 425 each include a stack of memory where each layer of memory is electrically connected (e.g., a first layer memory die connected to a second layer memory die, the second layer memory die connected to a third layer memory die, etc., for each respective stack). In some cases, HBM stack 420 and/or HBM stack 425 may include 3D stacked HBM. As shown, a first layer of HBM stack 420 may be electrically connected to HBM 3D PHY 450. Additionally, or alternatively, a first layer of HBM stack 425 may be electrically connected to HBM 3D PHY 455. In some cases, the electrical connections of HBM stack 420 and/or HBM stack 425 may include at least one of TSVs, TSV-BPM bonding, Cu-Cu connections, hybrid bonding, microbumps, wafer-on-wafer bonding, and/or integrated-SoC (SoIC) bonding. In the illustrated example, the layers of HBM stack 420 may connect electrically via TSV 430, where TSV may include one or more through-silicon vias. As shown, HBM 3D PHY 450 may connect electrically to the first layer of HBM stack 420 via TSV 430.

In the illustrated example, HBM 3D PHY 450 may be formed on a surface (e.g., front surface) of compute die 415. Additionally, or alternatively, HBM 3D PHY 455 may be formed on a surface (e.g., front surface) of compute die 415. In some cases, HBM PHY 445 may be formed on a surface (e.g., front surface) of compute die 415, and/or HBM PHY 440 may be formed on a surface (e.g., front surface) of base die 410. As shown, compute die 415 may connect electrically to silicon interposer 435 via electrical connection 460. In some examples, electrical connection 460 may include at least one of TSVs, TSV-BPM bonding, Cu-Cu connections, hybrid bonding, microbumps, wafer-on-wafer bonding, and/or integrated-SoC (SoIC) bonding.

In some examples, compute die 415 may include a compute die of a GPU, CPU, NPU, etc. As shown, compute die 415 may be connected to silicon interposer 435 based on one or more HBM PHY 445 and/or based on one or more HBM PHY 440 on HBM base die 410 for improved processing capabilities.

In some embodiments, silicon interposer 435 may be formed using silicon, and/or other conductive and/or semiconductor materials and may be used to enable high bandwidth memory configurations with system 400 (e.g., enable a 3D integrated circuit (IC)). In some cases, silicon interposer 435 may include one or more connections for multiple HBM stacks. For example, silicon interposer 435 may include electrical connection 460 as an electrical connection to HBM stack 420 and/or HBM stack 425. In some cases, silicon interposer 435 may include a first to HBM stack 420 (e.g., electrical connection 460), a second electrical connection to HBM stack 425, a third electrical connection to a third HBM stack, and so on. In some cases, silicon interposer 435 may be configured to connect multiple compute dies (e.g., connect compute die 415 to at least a second compute die, and so on). In some embodiments, multiple compute dies may be connected via silicon interposer 435 in one memory compute package (e.g., one AI compute SoC package). The high bandwidth memory systems and methods of system 400 (e.g., 3D stacked HBM and 2.5D stacked HBM) enable higher speed data transfers, and higher bandwidth processing for advanced AI programs and complex computations, such as computer vision, weather prediction.

In some examples, silicon interposer 435 may connect compute die 415 with a substrate. For example, silicon interposer 435 may be formed on a substrate. In some cases, HBM PHY 440 or HBM PHY 445 may include a physical layer providing physical interconnectivity, including power and/or communication connectivity with compute die 415. In some cases, HBM PHY 440, HBM PHY 445, HBM 3D PHY 450, and/or HBM 3D PHY 450 may be configured to receive and/or send address, data, and/or control signals between connected components (e.g., between HBM stack 405, base die 410, compute die 415, HBM stack 420, and/or HBM stack 425). In some cases, HBM PHY 440, HBM PHY 445, HBM 3D PHY 450, and/or HBM 3D PHY 455 may include one or more clocking mechanisms to ensure information is received and/or transmitted correctly (e.g., synchronously or asynchronously according to the application or usc). HBM PHY 440, HBM PHY 445, HBM 3D PHY 450, and/or HBM 3D PHY 455 may identify and correct data communication errors (e.g., in conjunction with a memory controller, HBM controller, etc.). In some examples, each compute die (e.g., compute die 415) may include a controller (e.g., for timing control, data communication control). Alternatively, one controller may be configured to control multiple compute dies (e.g., for timing control, data communication control over system 400).

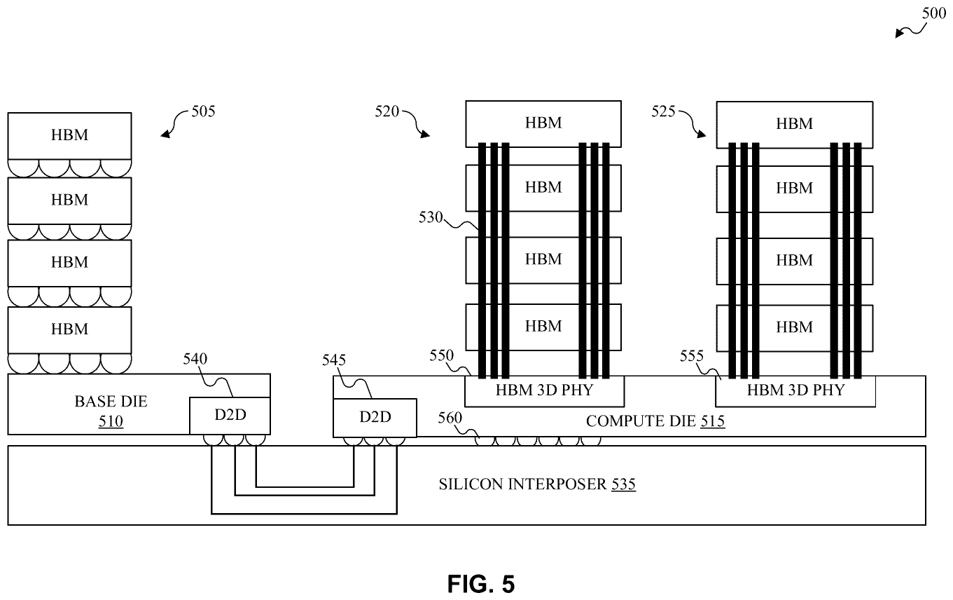

FIG. 5 illustrates an example system 500 in accordance with one or more implementations as described herein. System 500 may represent a side view of a system based on high bandwidth memory configurations. In the illustrated example, system 500 includes HBM stack 505, base die 510, compute die 515, HBM stack 520, HBM stack 525, TSV 530, silicon interposer 535, D2D interface 540, D2D interface 545, HBM 3D PHY 550, and HBM 3D PHY 555. As shown, HBM stack 505 includes a stack of HBM. As shown, compute die 515 may connect electrically to silicon interposer 535 via electrical connection 560. In some examples, electrical connection 560 may include at least one of TSVs, TSV-BPM bonding, Cu—Cu connections, hybrid bonding, microbumps, wafer-on-wafer bonding, and/or integrated-SoC (SoIC) bonding.

As shown, base die 510 may include D2D interface 540 and compute die 515 may include D2D interface 545. As shown, compute die 515 may connect electrically to base die 510 via D2D interface 545 and D2D interface 540. Accordingly, data may be sent between HBM stack 520 and HBM stack 505 via D2D interface 545 and D2D interface 540.

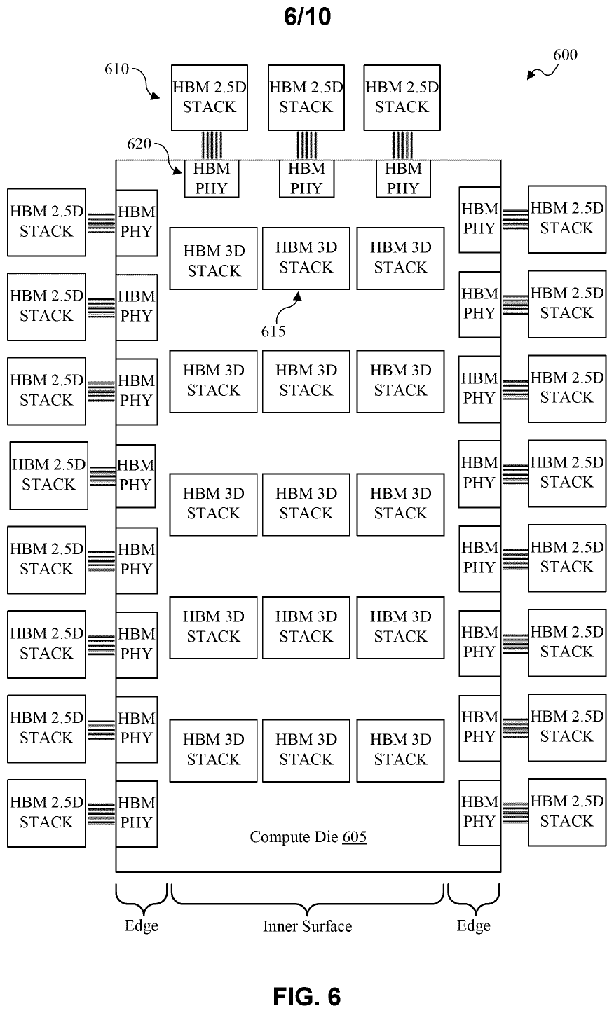

FIG. 6 illustrates an example system 600 in accordance with one or more implementations as described herein. System 600 may represent a top-down view of a system based on high bandwidth memory configurations. System 600 may include compute die 605, HBM stack 610, HBM stack 615, HBM PHY 620. In some examples, compute die 605 may be an example of compute die 515, HBM stack 610 may be an example of HBM stack 505, HBM stack 615 may be an example of HBM stack 520 or HBM stack 525, HBM PHY 620 may be an example of HBM 3D PHY 550 or HBM 3D PHY 555, and a silicon interposer of system 600 (e.g., electrically connected to compute die 605) may be an example of silicon interposer 535. In some cases, compute die 605 may be formed on a silicon interposer of system 600.

As illustrated, the system 600 may include a combination of stacked memory (e.g., a combination of 2.5D and 3D stacked HBM). As shown, the combination of stacked memory may include multiple 2.5D HBM stacks (e.g., HBM stack 610) and multiple 3D HBM stacks (e.g., HBM stack 615). As shown, the multiple 2.5D HBM stacks may attach to compute die 605. As shown, HBM stack 610 may connect to compute die 605 via HBM PHY 620. In some cases, HBM stack 615 may connect to compute die 605 via an HBM 3D PHY (e.g., HBM 3D PHY 550, HBM 3D PHY 555).

In the illustrated example, one or more 2.5D HBM stacks (e.g., HBM stack 610) may attach to a side or an edge of compute die 605, while one or more 3D HBM stacks (e.g., HBM stack 615) may attach to an inner surface of compute die 605 (e.g., towards a central surface of compute die 605, apart from an edge of compute die 605). Additionally, or alternatively, one or more 2.5D HBM stacks may attach to a top edge, side edge, or bottom edge (bottom side) of compute die 605 relative to the illustrated example. As shown, HBM stack 610 may attach to a top edge (top side) of compute die 605.

Illustrated are exemplary arrangements, configurations and numbers of 2.5D and 3D stacked HBMs. Any number of 2.5D and/or 3D HBM stacks may be connected. For example, compute die 605 may have 4, 8, 12, 16, 32 3D HBM stacks on a front surface of compute die 605. In some examples, one or more additional compute dies may attach to compute die 605 via D2D connections.

The high bandwidth memory systems and methods described herein enable improved performance, including higher speed data transfers, higher capacity, and higher bandwidth processing for programs such as workflow simulations, climate modeling, and other AI applications.

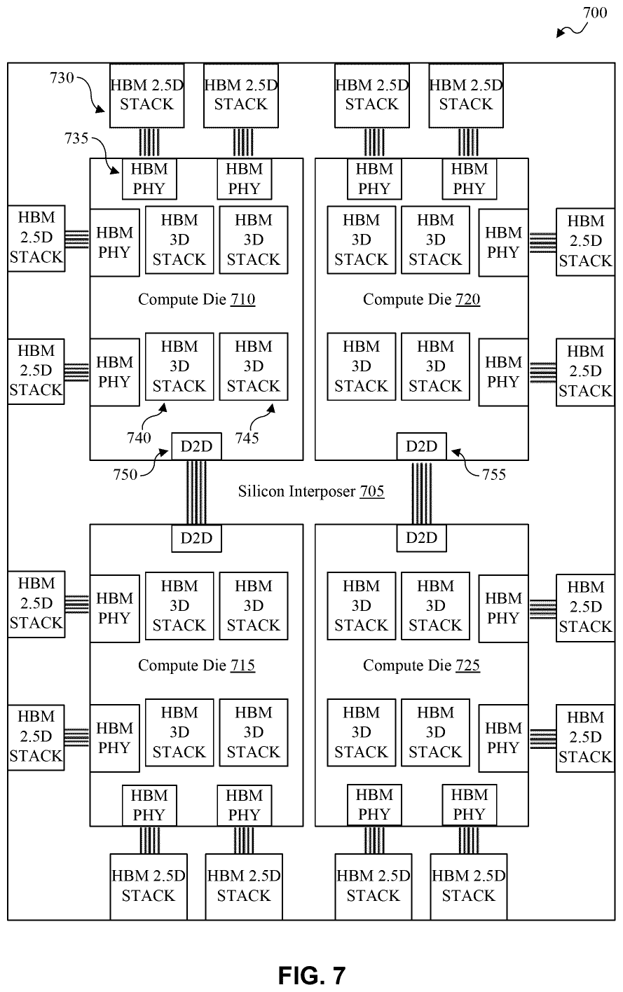

FIG. 7 illustrates an example system 700 in accordance with one or more implementations as described herein. System 700 may represent a top-down view of a system based on high bandwidth memory configurations. System 700 may include silicon interposer 705, compute die 710, compute die 715, compute die 720, compute die 725, and one or more 2.5D HBM stacks (e.g., HBM stack 730). As shown, compute die 710 may include one or more HBM PHYs (e.g., HBM PHY 735), one or more 3D HBM stacks (e.g., HBM stack 740, HBM stack 745), and at least one D2D interface (e.g., D2D interface 750, D2D interface 755). In some examples, silicon interposer 705 may be an example of a silicon interposer of system 600, compute die 710, compute die 715, compute die 720, and/or compute die 725 may be respective examples of compute die 605, HBM stack 730 may be an example of HBM stack 610, HBM PHY 735 may be an example of HBM PHY 620, and HBM stack 740 or HBM stack 745 may be an example of HBM stack 615. In some cases, silicon interposer 705 may be formed on a substrate.

In the illustrated example, compute die 710, compute die 715, compute die 720, and/or compute die 725 may be formed on silicon interposer 705. In some examples, silicon interposer 705 may connect compute die 710 to HBM PHY 735, connect HBM stack 730 to compute die 710, connect a base die of HBM stack 730 to compute die 710, connect HBM stack 740 to compute die 710, connect HBM stack 740 to another HBM stack (e.g., HBM stack 745) on a front surface of compute die 710, connect D2D interface 750 to compute die 710, and connect at least one compute die (e.g., compute die 710) to at least one other computer die (e.g., compute die 715, compute die 720, and/or compute die 725).

As shown, D2D interface 750 may connect compute die 710 to compute die 715. Additionally, or alternatively, D2D interface 755 may connect compute die 720 to compute die 725, increasing the capacity and bandwidth capabilities of system 700. In some cases, a D2D interface may connect compute die 710 to compute die 720, and/or a D2D interface may connect compute die 715 to compute die 725.

In the illustrated example, a compute die of system 700 may include any number of 3D HBM stacks (e.g., 1, 2, 4, 8, 16, 32 HBM memory die layers, etc.). Additionally, as illustrated, a compute die may include one or more 2.5D HBM stacks attached to the top edge, bottom edge, right edge, and/or left edge, based on an HBM PHY connection (e.g., HBM PHY 735). The numbers, configurations, arrangements, and connections are provided as examples and not intended in any way as limiting.

In some embodiments, HBM stack 740 may include a stack of DRAM connected via TSV to an HBM 3D PHY (e.g., HBM 3D PHY 450). The HBM stack 740 may be attached to compute die 710 and communicate via one or more controllers (e.g., one or more microcontrollers, one or more memory controllers, and/or one or more HBM controllers). In some cases, HBM stack 740 may communicate with any compute die of system 700, with 3D HBM stacks of compute die 710 and/or 3D HBM stacks of other compute dies, with 2.5D HBM stacks of system 700 (e.g., HBM stack 730). In some cases, HBM stack 730 may communicate (e.g., via silicon interposer 705) with any compute die of system 700, with any 3D HBM stacks of system 700 (e.g., HBM stack 740), with any other 2.5D HBM stacks of system 700, and the like.

In some embodiments, silicon interposer 705 may be formed using silicon, and/or other conductive and/or semiconductor materials and may be used to enable high bandwidth memory configurations with system 700. Silicon interposer 705 may provide connectivity between one or more 2.5D HBM stacks and/or one or more 3D HBM stacks. In some examples, silicon interposer 705 may be formed on a substrate. One or more compute dies and one or more 2.5D HBM stacks may be formed on silicon interposer 705. One or more 3D HBM stacks may be formed on the compute dies of system 700.

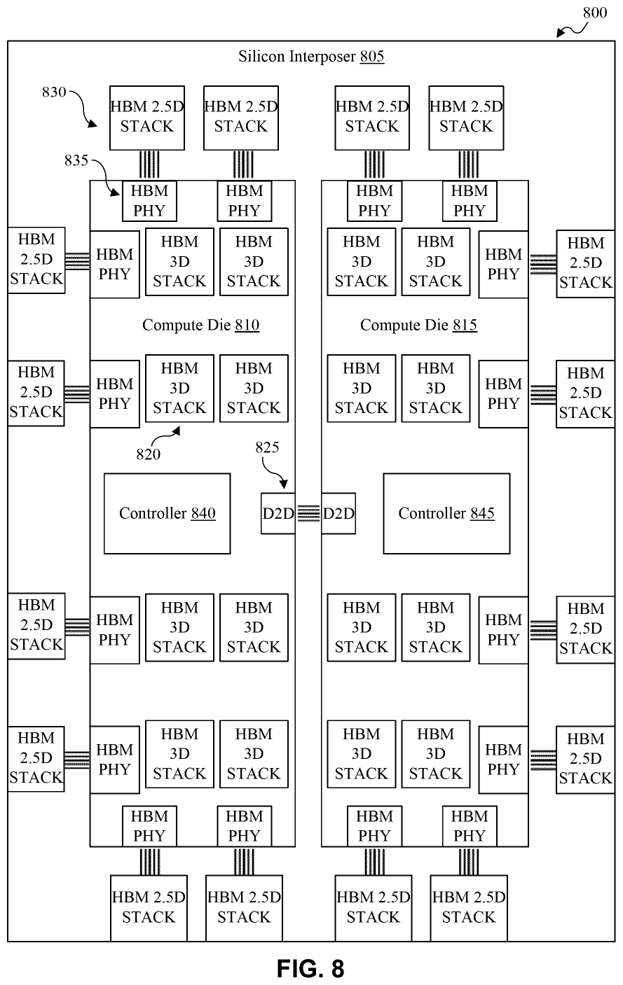

FIG. 8 illustrates an example system 800 in accordance with one or more implementations as described herein. System 800 may represent a top-down view of a system based on high bandwidth memory configurations. System 800 may include silicon interposer 805, compute die 810, compute die 815, and one or more 2.5D HBM stacks (e.g., HBM stack 830). As shown, compute die 810 may include one or more HBM PHYs (e.g., HBM PHY 835), one or more 3D HBM stacks (e.g., HBM stack 820), at least one D2D interface (e.g., D2D interface 825), and at least one controller (e.g., controller 840). As shown, compute die 815 may include one or more HBM PHYs, one or more 3D HBM stacks, at least one D2D interface (e.g., D2D interface 825), and at least one controller (e.g., controller 845). In some examples, silicon interposer 805 may be an example of silicon interposer 705, compute die 810 and/or compute die 815 may be examples of compute die 710, compute die 715, compute die 720, and/or compute die 725, HBM stack 830 may be an example of HBM stack 730, HBM PHY 835 may be an example of HBM PHY 735, HBM stack 820 may be an example of HBM stack 740 or HBM stack 745, D2D interface 825 may be an example of D2D interface 750 or D2D interface 755. As shown, D2D interface 825 may connect compute die 810 (and/or components of compute die 810) to compute die 815 (and/or components of compute die 815). In some cases, silicon interposer 805 may be formed on a substrate.

In some examples, controller 840 and/or controller 845 may include a microcontroller, memory controller, and/or an HBM controller. In some cases, controller 840 and/or controller 845 may be referred to as a host of system 800. In some embodiments, controller 840 and/or controller 845 may be configured to coordinate and manage addressing, transmitting, and/or receiving memory commands (e.g., read, write, modify, deallocate, garbage collection, etc.) in relation to and/or in conjunction with compute die 810, compute die 815, one or more 2.5D HBM stacks, one or more HBM PHYs, one or more 3D HBM stacks, one or more 3D HBM PHYS of the 3D HBM stacks, one or more D2D interfaces, and/or at least one controller of system 800.

In some examples, controller 840 and/or controller 845 may include one or more processing units, such as an ASIC, CPU, GPU, NPU, or TPU, for example. In some cases, controller 840 and/or controller 845 may send instructions and/or data to the 3D HBM stacks and/or the 2.5D HBM stacks of system 800. In some cases, controller 840 and/or controller 845 may prioritize bandwidth based on utilization of the 2.5D HBM stacks and/or the 3D HBM stacks of system 800.

In some cases, controller 840 and/or controller 845 may manage memory data operations based on the memory configurations, amount of memory, locations of memory in system 800. In some embodiments, controller 840 and/or controller 845 may divide data operations between compute dies (e.g., between compute die 810 and compute die 815) based on the number of 2.5D HBM stacks, the number of 3D HBM stacks, the number of layers (e.g., memory die layers) in the 2.5D HBM stacks, the number of layers (e.g., memory die layers) in the 3D HBM stacks in system 800. In some cases, to manage memory data operations, controller 840 and/or controller 845 may determine the number of compute dies, the number of HBM stacks per compute die, number of memory die layers per HBM stack, and/or number of memory die layers per compute die. Additionally, or alternatively, to manage memory data operations, controller 840 and/or controller 845 may determine the amount of memory per compute die, the amount of memory in system 800, etc. In some cases, to manage memory data operations, controller 840 and/or controller 845 may determine the amount of 2.5D HBM memory per compute die, the amount of 2.5D HBM memory in system 800, the amount of 3D HBM memory per compute die, the amount of 3D HBM memory in system 800.

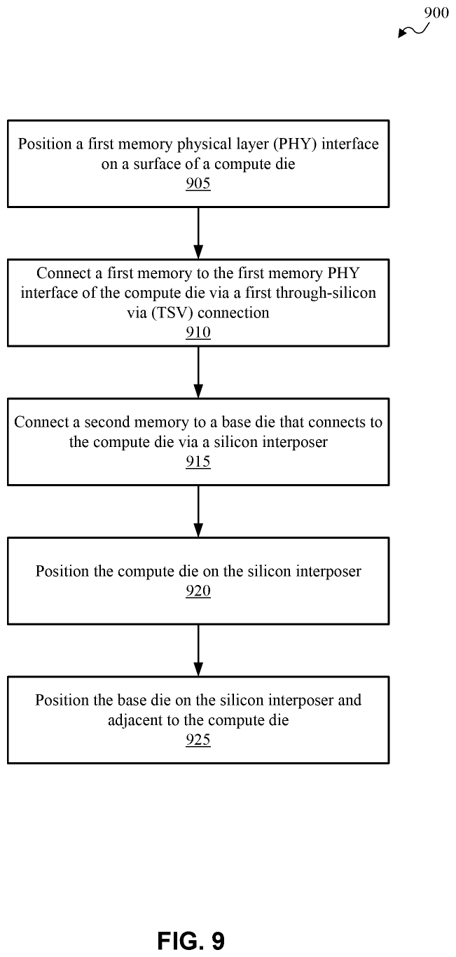

FIG. 9 depicts a flow diagram illustrating an example method 900 associated with the disclosed systems, in accordance with example implementations described herein. In some configurations, method 900 may be based on a semiconductor fabrication process implemented by semiconductor fabrication hardware, firmware, and/or software (e.g., machine 105). In some configurations, method 900 may be implemented in conjunction with machine 105, components of machine 105, or any combination thereof. The depicted method 900 is just one implementation and one or more operations of method 900 may be rearranged, reordered, omitted, and/or otherwise modified such that other implementations are possible and contemplated.

At 905, method 900 may include positioning a first memory physical layer (PHY) interface on a surface of a compute die. For example, HBM 3D PHY 450 may be positioned on a surface of computing die 415.

At 910, method 900 may include connecting a first memory to the first memory PHY interface of the compute die via a first through-silicon via (TSV) connection. For example, TSV 430 may connect a 3D HBM stack (e.g., HBM stack 420) to HBM 3D PHY 450.

At 915, method 900 may include connecting a second memory to a base die that connects to the compute die via a silicon interposer. For example, an electrical connection (e.g., TSV, microbumps, etc.) may connect a 2.5D HBM stack (e.g., HBM stack 405) to base die 410.

At 920, method 900 may include positioning the compute die on the silicon interposer. For example, compute die 415 may be positioned on silicon interposer 435. In some cases, an electrical connection (e.g., TSV, microbumps, etc.) may connect compute die 415 to silicon interposer 435.

At 925, method 900 may include positioning the base die on the silicon interposer (e.g., adjacent to the compute die). For example, base die 410 may be positioned on silicon interposer 435 adjacent to compute die 415.

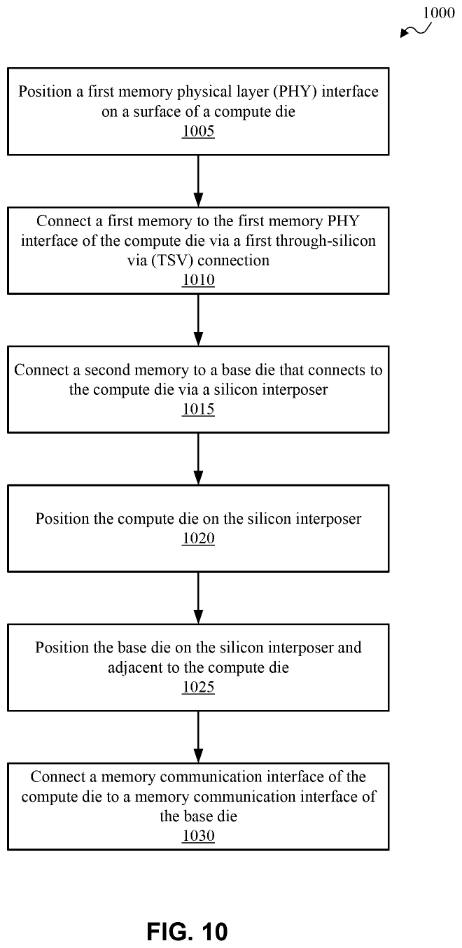

FIG. 10 depicts a flow diagram illustrating an example method 1000 associated with the disclosed systems, in accordance with example implementations described herein. In some configurations, method 1000 may be based on a semiconductor fabrication process implemented by semiconductor fabrication hardware, firmware, and/or software (e.g., machine 105). In some configurations, method 1000 may be implemented in conjunction with machine 105, components of machine 105, or any combination thereof. The depicted method 1000 is just one implementation and one or more operations of method 1000 may be rearranged, reordered, omitted, and/or otherwise modified such that other implementations are possible and contemplated.

At 1005, method 1000 may include positioning a first memory physical layer (PHY) interface on a surface of a compute die. For example, HBM 3D PHY 450 may be positioned on a surface of computing die 415.

At 1010, method 1000 may include connecting a first memory to the first memory PHY interface of the compute die via a first through-silicon via (TSV) connection. For example, TSV 430 may connect a 3D HBM stack (e.g., HBM stack 420) to HBM 3D PHY 450.

At 1015, method 1000 may include connecting a second memory to a base die that connects to the compute die via a silicon interposer. For example, an electrical connection (e.g., TSV, microbumps, etc.) may connect a 2.5D HBM stack (e.g., HBM stack 405) to base die 410.

At 1020, method 1000 may include positioning the compute die on the silicon interposer. For example, compute die 415 may be positioned on silicon interposer 435. In some cases, an electrical connection (e.g., TSV, microbumps, etc.) may connect compute die 415 to silicon interposer 435.

At 1025, method 1000 may include positioning the base die on the silicon interposer. For example, base die 410 may be positioned on silicon interposer 435 adjacent to compute die 415.

At 1030, method 1000 may include connecting a memory communication interface of the compute die to a memory communication interface of the base die. For example, a memory communication interface of compute die 415 connects, via silicon interposer 435, to a memory communication interface of base die 410. For example, HBM PHY 445 and HBM PHY 440 connect compute die 415 to base die 410 via silicon interposer 435. Alternatively, D2D interface 545 and D2D interface 540 connect compute die 415 to base die 410 via silicon interposer 435.

In the examples described herein, the configurations and operations are example configurations and operations, and may involve various additional configurations and operations not explicitly illustrated. In some examples, one or more aspects of the illustrated configurations and/or operations may be omitted. In some embodiments, one or more of the operations may be performed by components other than those illustrated herein. Additionally, or alternatively, the sequential and/or temporal order of the operations may be varied.

Certain embodiments may be implemented in one or a combination of hardware, firmware, and software. Other embodiments may be implemented as instructions stored on a computer-readable storage device, which may be read and executed by at least one processor to perform the operations described herein. A computer-readable storage device may include any non-transitory memory mechanism for storing information in a form readable by a machine (e.g., a computer). For example, a computer-readable storage device may include read-only memory (ROM), random-access memory (RAM), magnetic disk storage media, optical storage media, flash-memory devices, and other storage devices and media.

The word “exemplary” is used herein to mean “serving as an example, instance, or illustration.” Any embodiment described herein as “exemplary” is not necessarily to be construed as preferred or advantageous over other embodiments. The terms “computing device,” “user device,” “communication station,” “station,” “handheld device,” “mobile device,” “wireless device” and “user equipment” (UE) as used herein refers to a wireless communication device such as a cellular telephone, smartphone, tablet, netbook, wireless terminal, laptop computer, a femtocell, High Data Rate (HDR) subscriber station, access point, printer, point of sale device, access terminal, or other personal communication system (PCS) device. The device may be either mobile or stationary.

As used within this document, the term “communicate” is intended to include transmitting, or receiving, or both transmitting and receiving. This may be particularly useful in claims when describing the organization of data that is being transmitted by one device and received by another, but only the functionality of one of those devices is required to infringe the claim. Similarly, the bidirectional exchange of data between two devices (both devices transmit and receive during the exchange) may be described as ‘communicating’, when only the functionality of one of those devices is being claimed. The term “communicating” as used herein with respect to a wireless communication signal includes transmitting the wireless communication signal and/or receiving the wireless communication signal. For example, a wireless communication unit, which is capable of communicating a wireless communication signal, may include a wireless transmitter to transmit the wireless communication signal to at least one other wireless communication unit, and/or a wireless communication receiver to receive the wireless communication signal from at least one other wireless communication unit.

Some embodiments may be used in conjunction with various devices and systems, for example, a Personal Computer (PC), a desktop computer, a mobile computer, a laptop computer, a notebook computer, a tablet computer, a server computer, a handheld computer, a handheld device, a Personal Digital Assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wireless Access Point (AP), a wired or wireless router, a wired or wireless modem, a video device, an audio device, an audio-video (A/V) device, a wired or wireless network, a wireless area network, a Wireless Video Arca Network (WVAN), a Local Area Network (LAN), a Wireless LAN (WLAN), a Personal Area Network (PAN), a Wireless PAN (WPAN), and the like.

Some embodiments may be used in conjunction with one way and/or two-way radio communication systems, cellular radio-telephone communication systems, a mobile phone, a cellular telephone, a wireless telephone, a Personal Communication Systems (PCS) device, a PDA device which incorporates a wireless communication device, a mobile or portable Global Positioning System (GPS) device, a device which incorporates a GPS receiver or transceiver or chip, a device which incorporates an RFID element or chip, a Multiple Input Multiple Output (MIMO) transceiver or device, a Single Input Multiple Output (SIMO) transceiver or device, a Multiple Input Single Output (MISO) transceiver or device, a device having one or more internal antennas and/or external antennas, Digital Video Broadcast (DVB) devices or systems, multi-standard radio devices or systems, a wired or wireless handheld device, e.g., a Smartphone, a Wireless Application Protocol (WAP) device, or the like.

Some embodiments may be used in conjunction with one or more types of wireless communication signals and/or systems following one or more wireless communication protocols, for example, Radio Frequency (RF), Infrared (IR), Frequency-Division Multiplexing (FDM), Orthogonal FDM (OFDM), Time-Division Multiplexing (TDM), Time-Division Multiple Access (TDMA), Extended TDMA (E-TDMA), General Packet Radio Service (GPRS), extended GPRS, Code-Division Multiple Access (CDMA), Wideband CDMA (WCDMA), CDMA 2000, single-carrier CDMA, multi-carrier CDMA, Multi-Carrier Modulation (MDM), Discrete Multi-Tone (DMT), Bluetooth™, Global Positioning System (GPS), Wi-Fi, Wi-Max, ZigBee™, Ultra-Wideband (UWB), Global System for Mobile communication (GSM), 2G, 2.5G, 3G, 3.5G, 4G, Fifth Generation (5G) mobile networks, 3GPP, Long Term Evolution (LTE), LTE advanced, Enhanced Data rates for GSM Evolution (EDGE), or the like. Other embodiments may be used in various other devices, systems, and/or networks.

Although an example processing system has been described above, embodiments of the subject matter and the functional operations described herein can be implemented in other types of digital electronic circuitry, or in computer software, firmware, or hardware, including the structures disclosed in this specification and their structural equivalents, or in combinations of one or more of them.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described herein can be implemented as one or more computer programs, i.e., one or more components of computer program instructions, encoded on computer storage medium for execution by, or to control the operation of, information/data processing apparatus. Alternatively, or in addition, the program instructions can be encoded on an artificially-generated propagated signal, for example a machine-generated electrical, optical, or electromagnetic signal, which is generated to encode information/data for transmission to suitable receiver apparatus for execution by an information/data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially-generated propagated signal. The computer storage medium can also be, or be included in, one or more separate physical components or media (for example multiple CDs, disks, or other storage devices).

The operations described herein can be implemented as operations performed by an information/data processing apparatus on information/data stored on one or more computer-readable storage devices or received from other sources.

The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, for example an FPGA (field programmable gate array) or an ASIC (application-specific integrated circuit). The apparatus can also include, in addition to hardware, code that creates an execution environment for the computer program in question, for example code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a component, component, subroutine, object, or other unit suitable for use in a computing environment. A computer program may, but need not, correspond to a file in a file system. A program can be stored in a portion of a file that holds other programs or information/data (for example one or more scripts stored in a markup language document), in a single file dedicated to the program in question, or in multiple coordinated files (for example files that store one or more components, sub-programs, or portions of code). A computer program can be deployed to be executed on one computer or on multiple computers that are located at one site or distributed across multiple sites and interconnected by a communication network.

The processes and logic flows described herein can be performed by one or more programmable processors executing one or more computer programs to perform actions by operating on input information/data and generating output. Processors suitable for the execution of a computer program include, by way of example, both general and special purpose microprocessors, and any one or more processors of any kind of digital computer. Generally, a processor will receive instructions and information/data from a read-only memory or a random access memory or both. The essential elements of a computer are a processor for performing actions in accordance with instructions and one or more memory devices for storing instructions and data. Generally, a computer will also include, or be operatively coupled to receive information/data from or transfer information/data to, or both, one or more mass storage devices for storing data, for example magnetic, magneto-optical disks, or optical disks. However, a computer need not have such devices. Devices suitable for storing computer program instructions and information/data include all forms of non-volatile memory, media and memory devices, including by way of example semiconductor memory devices, for example EPROM, EEPROM, and flash memory devices; magnetic disks, for example internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described herein can be implemented on a computer having a display device, for example a CRT (cathode ray tube) or LCD (liquid crystal display) monitor, for displaying information/data to the user and a keyboard and a pointing device, for example a mouse or a trackball, by which the user can provide input to the computer. Other kinds of devices can be used to provide for interaction with a user as well; for example, feedback provided to the user can be any form of sensory feedback, for example visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Embodiments of the subject matter described herein can be implemented in a computing system that includes a back-end component, for example as an information/data server, or that includes a middleware component, for example an application server, or that includes a front-end component, for example a client computer having a graphical user interface or a web browser through which a user can interact with an embodiment of the subject matter described herein, or any combination of one or more such back-end, middleware, or front-end components. The components of the system can be interconnected by any form or medium of digital information/data communication, for example a communication network. Examples of communication networks include a local area network (“LAN”) and a wide area network (“WAN”), an inter-network (for example the Internet), and peer-to-peer networks (for example ad hoc peer-to-peer networks).

The computing system can include clients and servers. A client and server are generally remote from each other and typically interact through a communication network. The relationship of client and server arises by virtue of computer programs running on the respective computers and having a client-server relationship to each other. In some embodiments, a server transmits information/data (for example an HTML page) to a client device (for example for purposes of displaying information/data to and receiving user input from a user interacting with the client device). Information/data generated at the client device (for example a result of the user interaction) can be received from the client device at the server.

While this specification contains many specific embodiment details, these should not be construed as limitations on the scope of any embodiment or of what may be claimed, but rather as descriptions of features specific to particular embodiments. Certain features that are described herein in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order shown, or sequential order, to achieve desirable results. In certain embodiments, multitasking and parallel processing may be advantageous.

Many modifications and other examples described herein set forth herein will come to mind to one skilled in the art to which these embodiments pertain having the benefit of the teachings presented in the foregoing descriptions and the associated drawings. Therefore, it is to be understood that the embodiments are not to be limited to the specific embodiments disclosed and that modifications and other embodiments are intended to be included within the scope of the appended claims. Although specific terms are employed herein, they are used in a generic and descriptive sense only and not for purposes of limitation.

What is claimed:

1. A method of configuring memory, the method comprising:
positioning a first memory physical layer (PHY) interface on a surface of a compute die;
connecting a first memory to the first memory PHY interface of the compute die via a first through-silicon via (TSV) connection;
connecting a second memory to a base die that connects to the compute die via a silicon interposer;
positioning the compute die and the base die on the silicon interposer.

2. The method of claim 1, wherein the first memory comprises a first memory die stacked on the first memory PHY interface and a second memory die stacked on the first memory die.

3. The method of claim 1, wherein:
the first memory die connects to the first memory PHY interface via the first TSV connection, and
the second memory die connects to the first memory die via the first TSV connection.

4. The method of claim 1, wherein the second memory comprises a third memory die stacked on the base die and a fourth memory die stacked on the third memory die.

5. The method of claim 4, wherein:
the third memory die connects to the base die via a second TSV connection, and
the fourth memory die connect to the third memory die via the second TSV connection.

6. The method of claim 1, wherein:
the compute die includes a second memory PHY interface of the compute die,
the first memory PHY interface is positioned on an inner surface of the compute die, and
the second memory PHY interface is positioned on a side of the compute die.

7. The method of claim 1, wherein the compute die includes a first die to die (D2D) interface positioned on a side of the compute die.

8. The method of claim 7, wherein the compute die connects to a second compute die via a second D2D interface of the compute die and the silicon interposer.

9. The method of claim 7, wherein the base die includes a memory PHY interface of the base die or a D2D interface of the base die.

10. The method of claim 1, wherein the second memory or the first memory comprises at least one of high-bandwidth memory, static random-access memory, dynamic random-access memory, or flash memory.

11. The method of claim 1, wherein the compute die comprises a graphical processing unit die.

12. A memory package comprising:
a first memory physical layer (PHY) interface positioned on a surface of a compute die;
a first memory connected to the first memory PHY interface of the compute die via a first through-silicon via (TSV) connection;
a base die coupled with the compute die and positioned on a silicon interposer, wherein the compute die is positioned on the silicon interposer and connected to the base die via the silicon interposer; and
a second memory connected to the base die.

13. The memory package of claim 12, wherein the first memory comprises a first memory die stacked on the first memory PHY interface and a second memory die stacked on the first memory die.

14. The memory package of claim 12, wherein:
the first memory die connects to the first memory PHY interface via the first TSV connection, and
the second memory die connects to the first memory die via the first TSV connection.

15. The memory package of claim 12, wherein the second memory comprises a third memory die stacked on the base die and a fourth memory die stacked on the third memory die.

16. The memory package of claim 15, wherein:
the third memory die connects to the base die via a second TSV connection, and
the fourth memory die connect to the third memory die via the second TSV connection.

17. The memory package of claim 12, wherein:
the compute die includes a second memory PHY interface of the compute die,
the first memory PHY interface is positioned on an inner surface of the compute die, and
the second memory PHY interface is positioned on a side of the compute die.

18. A system on chip (SoC) comprising:
a compute die positioned on a silicon interposer;
a base die coupled with the compute die and positioned on the silicon interposer; and
a memory coupled with the compute die and the base die, the memory comprising:
a first memory physical layer (PHY) interface positioned on a surface of the compute die;
a first memory connected to the first memory PHY interface of the compute die via a first through-silicon via (TSV) connection; and
a second memory connected to the base die via a second TSV connection.

19. The SoC of claim 18, wherein the first memory comprises a first memory die stacked on the first memory PHY interface and a second memory die stacked on the first memory die. 20 The SoC of claim 18, wherein:
the first memory die connects to the first memory PHY interface via the first TSV connection, and
the second memory die connects to the first memory die via the first TSV connection.
